(19) United States
(12) Patent Application Publication
(10) Pub. No.: US 2006/0001475 A1
(43) Pub. Date: Jan. 5, 2006

(54) Class-AB beta helper to reduce effects of mirror perturbation

(76) Inventor: John J. Price JR., Eagan, MN (US)

Correspondence Address: TEXAS INSTRUMENTS INCORPORATED, P O BOX 655474, M/S 3999, DALLAS, TX, 75265, US

(21) Appl. No.: 10/881,284

(22) Filed: Jun. 30, 2004

(51) Int. Cl. G11C 7/00

(52) U.S. Cl. 327/538

(57) ABSTRACT

The present invention achieves technical advantages as a write head mirror circuit (30) having a Class-AB beta helper (32) providing immunity to severe perturbations of mirror current at the mirror circuit output. The typical single transistor beta helper is replaced with a Class-AB beta helper, advantageously preventing the beta helper from turning off, thereby providing output mirror current accuracy.

### FIELD OF THE INVENTION

The present invention relates generally to a preamp writer for a hard disk drive (HDD), and more particularly to stabilizing a write current mirror feeding an H-bridge driving a write head.

### BACKGROUND OF THE INVENTION

In preamp writers for disk drives it has been an ongoing problem to stabilize a write current mirror feeding an H-bridge that drives a write current to a write head. The H-bridge switches high currents to an inductive load, and so the voltage excursions are high. These perturbations wreak havoc on the write current mirror which accepts a divided-down write current (typically 10:1 or 20:1) and which attempts to provide a stable output current at the H-switch.

Traditionally, this write current mirror has had a normal beta-helper transistor removed in an attempt to increase write current stability and immunity to the large output perturbations. Removing the beta-helper transistor, however, results in mirror inaccuracy which must normally be compensated for in more complex circuitry which has typically suffered from less accuracy than desired.

FIG. 1 shows a traditional write current mirror circuit 10 that lacks a beta helper transistor. Transistor Q10 is an input transistor, having a collector-base short instead of a beta helper transistor thereacross. Thus, the base currents of input transistor Q10 and output transistor Q13 understandably contribute error to the mirror current accuracy. This is especially true with high ratio current mirrors, as circuit 10 which has a 1:20 ratio. Transistors Q11, MN7, Q12, MP1 and MP2 are used to reduce this base current error, although this technique generally suffers from considerable inaccuracy due to Early effects and transistor matching difficulties. Transistor Q13 supplies the mirrored write current, which is switched on and off by transistor MN8 (shown here always on).

FIG. 2 shows a simplified schematic of a normal mirror circuit 20 having a beta helper transistor Q2B. Capacitor C1 is provided to insure AC stability of this mirror circuit 20, but this beta helper transistor Q2B contributes to the time it takes for the mirror circuit 20 to recover from severe perturbations.

FIG. 3 shows the waveforms associated with the standard beta helper mirror circuit 20 of FIG. 2. Curve 22 is the voltage applied at the mirror output, transistor Q3's collector, which is not untypical of what is seen in a write driver of a H-switch. Curve 24 is the voltage at the bases of transistors Q1 and Q3. When the voltage at transistor Q3's collector swings high at about 1 ns, this base voltage tends to follow as induced by parasitic capacitances and stored charge. As the base voltage of transistors Q1 and Q3 rises, transistor Q2B, the beta helper, turns off, allowing transistor Q1 to come into saturation. Curve 26 is the voltage at transistor Q1's collector, and dips dramatically until the voltage at the bases of transistors Q1 and Q3 recovers to its original voltage. In the meantime, the current output of the mirror circuit current at transistor Q3's collector, shown as curve 28, has varied from its quiescent 40 mA up to 80 mA and down to about 20 mA, and taking over 5 ns to recover. This output current 28 is completely unacceptable in a write driver that should be operating at above 1 Gb/s.

### SUMMARY OF THE INVENTION

The present invention achieves technical advantages as a write head mirror circuit having a Class-AB beta helper providing immunity to severe perturbations of mirror current at the mirror output. The typical single transistor beta helper is replaced with a Class-AB beta helper, advantageously preventing the beta helper from turning off, thereby providing output mirror accuracy.

### BRIEF DESCRIPTION OF THE DRAWINGS

FIG. 1 is a schematic of a prior art write current mirror circuit without a beta helper transistor;

FIG. 2 is a schematic of a prior art write current mirror circuit with a beta helper transistor;

FIG. 3 is a graph of currents and voltages of the circuit of FIG. 2 showing the dramatic swing of mirror current;

FIG. 4 is a schematic of one embodiment of the invention being a current mirror circuit with a Class-AB beta helper; and

FIG. 5 is a graph of voltages and current of the circuit of FIG. 4 showing the improved generally constant mirror current.

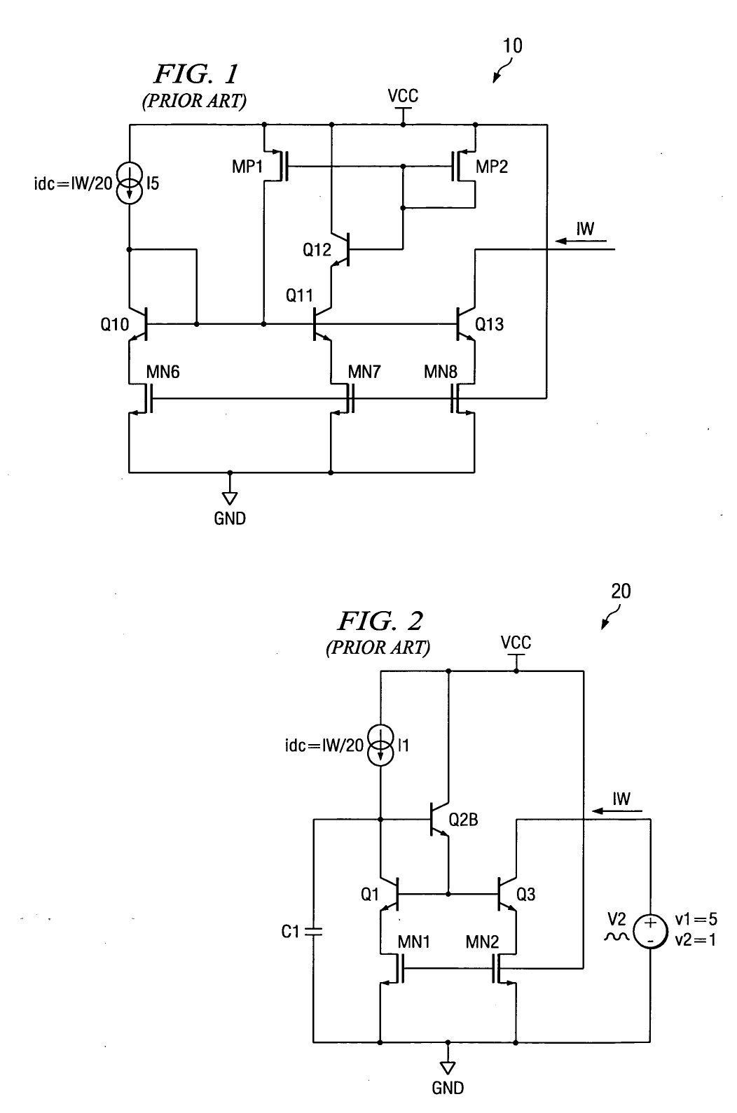

### DETAILED DESCRIPTION OF THE PREFERRED EMBODIMENT

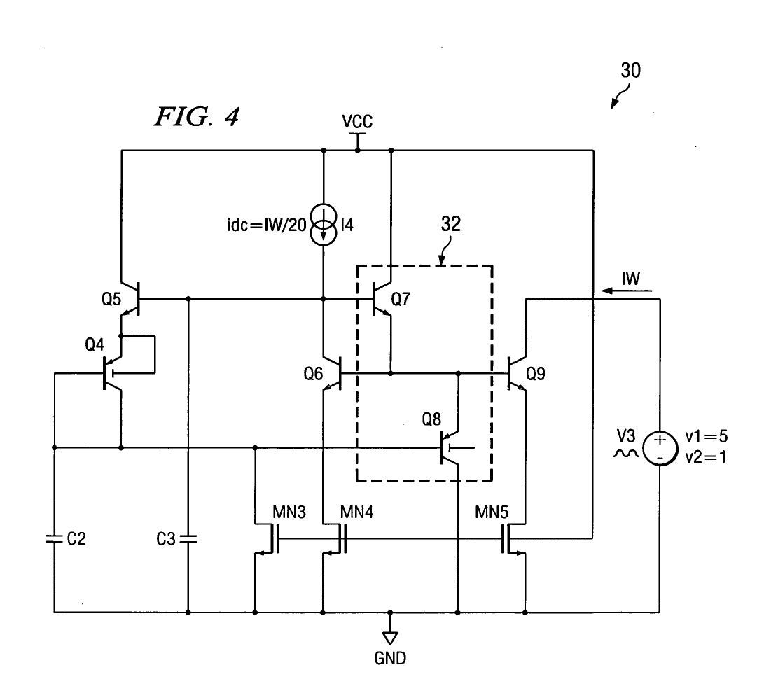

An improved write current mirror circuit 30 according to one embodiment of the invention having a Class-AB beta helper 32 is shown in FIG. 4. In addition to transistor Q7, the normal beta helper, a PNP transistor Q8 is added in parallel with transistor Q7. The base connections of transistors Q7 and Q8 are offset by the voltage developed across the transistors Q4 and Q5 in order to set up the correct bias condition. Transistors Q4 and Q5, with current source transistor MN3, provide the quiescent bias for transistors Q7 and Q8, comprising the beta helper transistors, advantageously arranged in a Class-AB configuration.

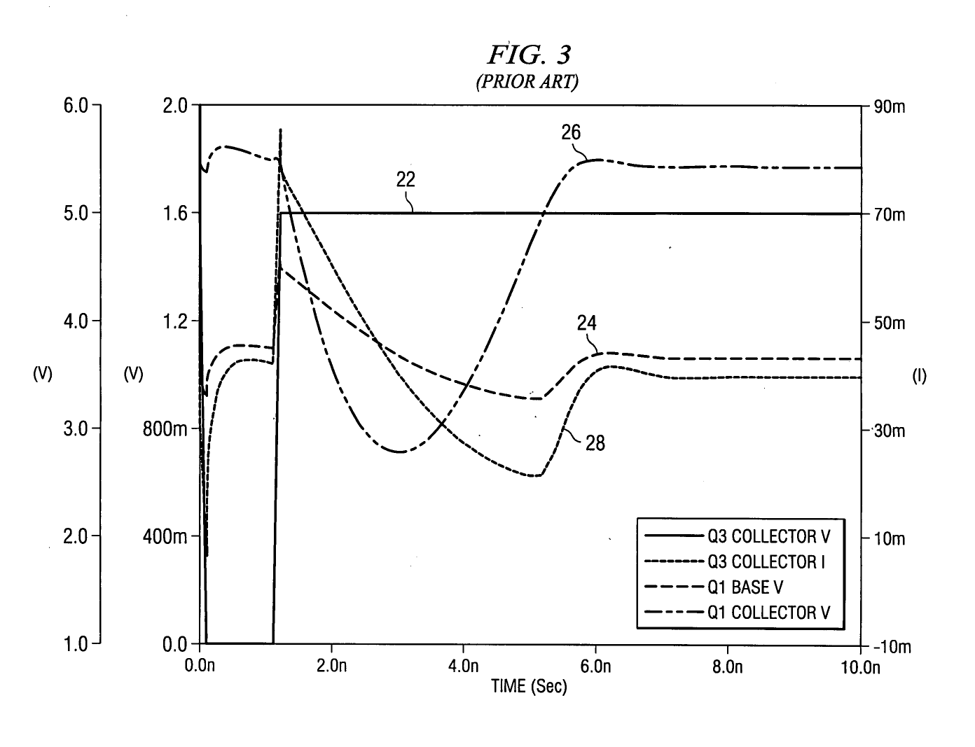

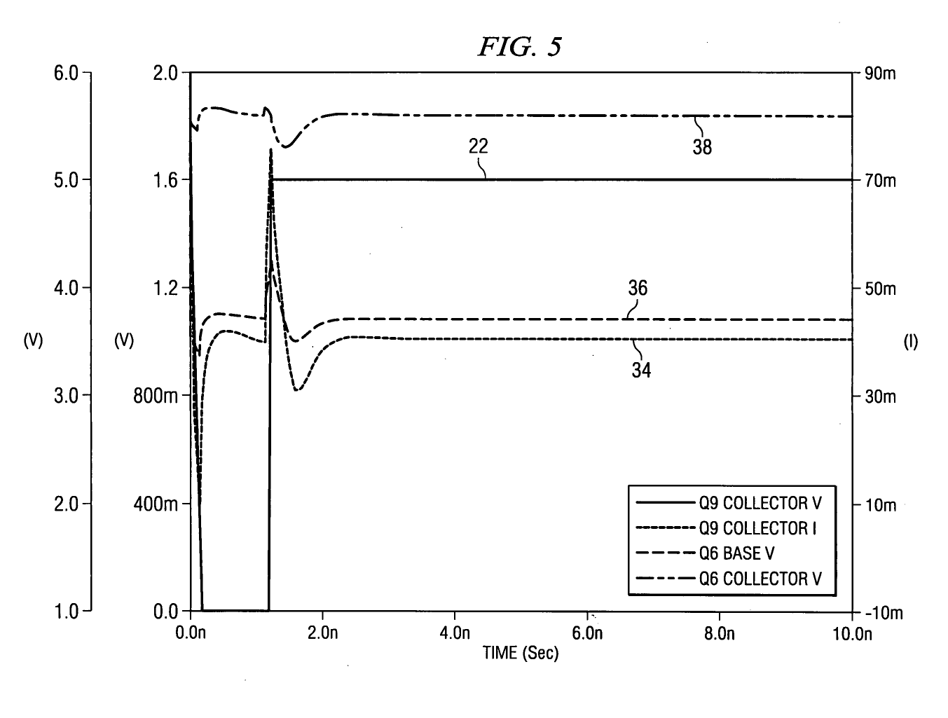

FIG. 5 shows the waveforms associated with the Class-AB beta helper mirror 32, comprising transistors Q7 and Q8, with the same perturbation as depicted for the normal beta helper mirror circuit 20 in FIGS. 2 and 3. One advantageous difference is that the input device, transistor Q6, does not saturate, as shown by curve 34, because PNP beta helper transistor Q8 prevents its base voltage from rising nearly as much. The output mirror current Iw, shown as curve 38, has nearly as large a variation initially. This can't be avoided due to the fast excursions of output transistor Q9's collector voltage. However, it can be seen by curve 38, that advantageously, the mirror current Iw undershoot is far less severe and it settles back in about 1 ns now, which is acceptable for a driver operating at above 1 Gb/s.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

We claim:

1. A write current mirror circuit, comprising;
an input transistor receiving an input current and coupled to an output transistor adapted to mirror the input transistor current to an output of the output transistor; and
a plurality of beta helper transistors coupled to the output transistor adapted to reduce perturbations in the mirrored current.

2. The circuit as specified in claim 1 wherein at least one of the beta helper transistors is in parallel with the with a second of the beta helper transistors.

3. The circuit as specified in claim 2 wherein the beta helper transistors are configured as a Class-AB beta helper.

4. The circuit as specified in claim 2 wherein the parallel beta helper transistor is a PNP transistor.

5. The circuit as specified in claim 4 wherein at least one of the beta helper transistors is an NPN transistor coupled to Vcc.

6. The circuit as specified in claim 5 wherein the PNP transistor is coupled between the NPN transistor and ground.

7. The circuit as specified in claim 1 wherein the mirrored current perturbations last less than about 1 ns.

8. The circuit as specified in claim 1 further comprising a bias transistor coupled between Vcc and the input transistor.

9. The circuit as specified in claim 1 further comprising a first capacitor coupled between the input transistor and ground.

10. The circuit as specified in claim 9 further comprising a second capacitor coupled between a base of the bias transistor and ground.
